(19) United States
(12) Patent Application Publication
(10) Pub. No.: US 2014/0020933 A1
(43) Pub. Date: Jan. 23, 2014

(54) THERMALLY CONDUCTIVE PRINTED CIRCUIT BOARDS

(71) Applicants: Nicholas Ryan Conley, Redwood City, CA (US); Logan Brook Hedin, San Francisco, CA (US); David Michael Miller, Portola Valley, CA (US)

(72) Inventors: Logan Brook Hedin, San Francisco, CA (US); David Michael Miller, Portola Valley, CA (US); Nicholas Ryan Conley, Redwood City, CA (US)

(21) Appl. No.: 13/943,588

(22) Filed: Jul. 16, 2013

Related U.S. Application Data
(60) Provisional application No. 61/672,685, filed on Jul. 17, 2012.

(51) Int. Cl. H05K 1/02

(52) U.S. Cl. CPC H05K 1/0201
USPC 174/252; 156/244.11; 427/98.4; 264/104

(57) ABSTRACT

A printed circuit board that includes a dielectric polymer layer having a thermally conductive agglomerate filler and an electrically conductive layer bonded to the dielectric polymer layer is provided. Methods of producing the printed circuit board are also provided. The subject printed circuit board and methods find use in a variety of different applications, including electronics applications.

### CROSS-REFERENCE TO RELATED APPLICATION

This application claims the benefit of priority under 35 U.S.C. §119(e) to U.S. Provisional Application Nos. 61/672,685 filed Jul. 17, 2012, the disclosure of which is incorporated by reference herein in its entirety.

### INTRODUCTION

Printed circuit boards (PCBs) are used to mechanically support and electrically connect electronic components using conductive pathways, or traces, etched from metal sheets laminated onto a non-conductive substrate. In general, the non-conductive substrates have poor thermal conductivity properties. PCBs can have holes drilled for each wire or electrical connection of each component. The components' leads are passed through the holes and soldered to the traces. This method of assembly is called through-hole construction. Soldering of the components can be done automatically by passing the board over a ripple, or wave, of molten solder in a wave-soldering machine. The conductive layers are typically made of thin copper foil and the thermally insulating layers of dielectric materials are typically laminated together.

Many electrical components generate heat. In order to dissipate the heat and keep the component cool, a heat sink with a higher heat capacity can be physically coupled to the electrical component. As the component generates heat, the thermal energy is transferred from the component to the heat sink which typically transfers the heat to the ambient air. This thermal energy transfer brings the electrical component into thermal equilibrium with the heat sink, lowering the temperature of the electrical component. The most common design of a heat sink is a metal device having many fins that increase the surface area of the heat sink. The high thermal conductivity of the heat sink and the large surface area allows the heat sink to rapidly transfer the thermal energy from the component to the surrounding air.

### SUMMARY

A printed circuit board that includes a dielectric polymer layer having a thermally conductive agglomerate filler and an electrically conductive layer bonded to the dielectric polymer layer is provided. Methods of producing the printed circuit board are also provided. The subject printed circuit board and methods find use in a variety of different applications, including electronics applications.

### BRIEF DESCRIPTION OF THE FIGURES

FIG. 1 shows a graph of thermal conductivity vs. % boron nitride (BN) agglomerate loading into the thermoplastic, according to embodiments of the present disclosure. The onset of the percolation regime occurs at about 45% BN agglomerate loading, and is characterized by a sharp increase in slope.

FIG. 2 shows a process flowchart for the preparation of thermally conductive thermoplastic-based laminates for printed circuit boards (PCBs), according to embodiments of the present disclosure.

### DETAILED DESCRIPTION

A printed circuit board that includes a dielectric polymer layer having a thermally conductive agglomerate filler and an electrically conductive layer bonded to the dielectric polymer layer is provided. Methods of producing the printed circuit board are also provided. The subject printed circuit board and methods find use in a variety of different applications, including electronics applications.

Before the present invention is described in greater detail, it is to be understood that aspects of the present disclosure are not limited to the particular embodiments described, and as such may, of course, vary. It is also to be understood that the terminology used herein is for the purpose of describing particular embodiments only, and is not intended to be limiting, since the scope of embodiments of the present disclosure will be defined only by the appended claims.

Where a range of values is provided, it is understood that each intervening value, to the tenth of the unit of the lower limit unless the context clearly dictates otherwise, between the upper and lower limit of that range and any other stated or intervening value in that stated range, is encompassed within embodiments of the present disclosure. The upper and lower limits of these smaller ranges may independently be included in the smaller ranges and are also encompassed within embodiments of the present disclosure, subject to any specifically excluded limit in the stated range. Where the stated range includes one or both of the limits, ranges excluding either or both of those included limits are also included in embodiments of the present disclosure.

Unless defined otherwise, all technical and scientific terms used herein have the same meaning as commonly understood by one of ordinary skill in the art to which this invention belongs. Although any methods and materials similar or equivalent to those described herein can also be used in the practice or testing of embodiments of the present disclosure, representative illustrative methods and materials are now described.

All publications and patents cited in this specification are herein incorporated by reference as if each individual publication or patent were specifically and individually indicated to be incorporated by reference and are incorporated herein by reference to disclose and describe the methods and/or materials in connection with which the publications are cited. The citation of any publication is for its disclosure prior to the filing date and should not be construed as an admission that embodiments of the present disclosure are not entitled to antedate such publication by virtue of prior invention. Further, the dates of publication provided may be different from the actual publication dates which may need to be independently confirmed.

It is noted that, as used herein and in the appended claims, the singular forms “a”, “an”, and “the” include plural referents unless the context clearly dictates otherwise. It is further noted that the claims may be drafted to exclude any optional element. As such, this statement is intended to serve as antecedent basis for use of such exclusive terminology as “solely,” “only” and the like in connection with the recitation of claim elements, or use of a “negative” limitation.

As will be apparent to those of skill in the art upon reading this disclosure, each of the individual embodiments described and illustrated herein has discrete components and features which may be readily separated from or combined with the features of any of the other several embodiments without departing from the scope or spirit of the present invention. Any recited method can be carried out in the order of events recited or in any other order which is logically possible.

In further describing various embodiments of the present disclosure, aspects of embodiments of the printed circuit boards are described first in greater detail. Following this description, a description of methods of producing the subject printed circuit boards is provided. Finally, a review of the various applications in which the printed circuit boards and methods find use is provided.

### Printed Circuit Boards

Embodiments of the present disclosure include a printed circuit board (PCB) that includes a dielectric polymer layer having a thermally conductive agglomerate filler. The printed circuit board may be configured to dissipate heat from one or more heat-producing components mounted on the PCB. The PCB may dissipate heat from a heat-producing component on the PCB by conducting heat generated by the heat-producing component away from the heat-producing component. For example, the PCB may be configured to conduct heat from the heat-producing component through the PCB away from the heat-producing component. In some instances, the PCB is configured to conduct heat from the heat-producing component to the PCB through the interface between the PCB and the heat-producing component. The heat-producing component may be directly mounted on the PCB, and as such, the PCB may be configured to conduct heat at the interface between the PCB and the heat-producing component from a surface of the PCB that directly contacts a surface of the heat-producing component. In other embodiments, the heat-producing component may be indirectly mounted on the PCB, and in these cases, the PCB may be configured to conduct heat from the heat-producing component to the PCB through one or more intervening layers, such as an electrically conductive layer, a bonding layer, a thermally conductive layer, and the like, which are described in more detail below.

In certain embodiments, the PCB is configured to dissipate heat from a heat-producing component mounted on the PCB, such that the PCB does not include a separate heat sink attached to the heat-producing component. In these embodiments, the thermal conductivity of the PCB is such that a sufficient amount of heat is conducted away from the heat-producing component through the PCB itself and dissipated to the ambient air, such that an additional heat sink for the heat-producing component is not required. In some cases, the thermal conductivity of the PCB is sufficient such that the PCB itself is configured to be the heat sink for the heat-producing component mounted on the PCB. In certain instances, the PCB is the only heat sink for the heat-producing component mounted on the PCB and a separate heat sink attached to the heat-producing component is not necessary to maintain the heat-producing component at thermal equilibrium within the component's acceptable operating temperature range.

Heat-producing components may include any one or more electronic components mounted on the PCB that produce heat during operation. For example, heat-producing components may include, but are not limited to, a relay (e.g., a solid state relay), a resistor (e.g., a variable resistor, a thermistor, a humistor, a varistor, etc.), a fuse, a circuit breaker, a capacitor, a transformer, a motor, a transducer, a diode (e.g., a light-emitting diode (LED), etc.), a transistor, an integrated circuit, and the like.

### Dielectric Polymer Layer

Embodiments of the printed circuit board (PCB) include a printed circuit board substrate. The PCB substrate is configured as a substrate on which the other layers and components of the PCB are disposed. In certain embodiments, the PCB substrate includes a dielectric polymer layer. The dielectric polymer layer may be configured as an electrical insulator, such that electric charges do not substantially flow through the PCB substrate (e.g., the dielectric polymer layer may be configured to have a high electrical resistance). For example, in certain instances, the dielectric polymer layer may have a dielectric constant of 15 or less, such as 12 or less, including 10 or less, or 9 or less, or 8 or less, or 7 or less, or 6 or less, or 5 or less, or 4.5 or less, or 4 or less, or 3.5 or less, or 3 or less, or 2.5 or less, for example 2 or less, or 1.5 or less.

In certain embodiments, the dielectric polymer layer has a relatively high glass transition temperature (T_{g}). The glass transition temperature of a material is a reversible transition of an amorphous material from a solid-like state into a molten or rubber-like state. In some cases, the dielectric polymer layer has a glass transition temperature of 100° C. or more, such as 150° C. or more, including 200° C. or more, or 250° C. or more, or 300° C. or more, or 350° C. or more, for instance 400° C. or more. A dielectric polymer layer that has a relatively high glass transition temperature may facilitate the production of a PCB that can withstand high processing temperatures during production of the PCB and/or operation at high temperatures for extended periods of time. For instance, a PCB that includes a dielectric polymer layer with a relatively high glass transition temperature may be configured to withstand high processing temperatures during production of the PCB and/or operate at temperatures of 100° C. or more, such as 150° C. or more, including 200° C. or more, or 250° C. or more, or 300° C. or more, or 350° C. or more, for instance 400° C. or more for extended periods of time without significant structural deformation or chemical degradation.

In certain instances, the dielectric polymer layer is substantially inflammable. In some cases, the dielectric polymer layer may be inflammable such that the dielectric polymer layer substantially resists burning (e.g., the dielectric polymer layer is substantially flame-retardant). The dielectric polymer layer may have a flammability rating on a standardized flammability scale, such that the dielectric polymer is classified as substantially inflammable. For example, the dielectric polymer layer may have a UL94 plastics flammability standard (Underwriters Laboratories of the USA) of V2, V1 or V0. A V2 UL94 flammability rating indicates that burning stops within 30 seconds on a vertical specimen with drips of flaming particles allowed. A V1 flammability rating indicates that burning stops within 30 seconds on a vertical specimen and drips of particles are allowed as long as they are not inflamed. A V0 flammability rating indicates that burning stops within 10 seconds on a vertical specimen and drips of particles are allowed as long as they are not inflamed.

In certain embodiments, the dielectric polymer layer has a coefficient of thermal expansion that is similar to the coefficient of thermal expansion of the electrically conductive layer of the PCB. In some cases, the dielectric polymer layer has a coefficient of thermal expansion that is similar to the coefficient of thermal expansion of the components mounted on the PCB. In certain instances, the dielectric polymer layer has a relatively low coefficient of thermal expansion. For example, the dielectric polymer layer may have a coefficient of thermal expansion similar to copper or silicon. A dielectric polymer layer that has a relatively low coefficient of thermal expansion may facilitate attachment of the electrically conductive layer and/or components to the PCB by minimizing differences in the rate of thermal expansion between the dielectric polymer layer and the attached electrically conductive layer and/or PCB components. In certain instances, minimizing differences in the rate of thermal expansion between the dielectric polymer layer and the attached electrically conductive layer and/or PCB components may facilitate a minimization in cracking or delamination of the electrically conductive layer from the dielectric polymer layer and/or a minimization in cracking or shearing of bonds (e.g., solder joints) between the dielectric polymer layer and the PCB components. In some cases, the dielectric polymer layer has a coefficient of thermal expansion of 50 ppm/° C. or less, such as 40 ppm/° C. or less, including 30 ppm/° C. or less, or 20 ppm/° C. or less, or 15 ppm/° C. or less, or 10 ppm/° C. or less, for example 5 ppm/° C. or less.

In certain embodiments, the dielectric polymer layer includes a dielectric polymer with a viscosity of 750 Pa-s or less, such as 700 Pa-s or less, including 650 Pa-s or less, or 600 Pa-s or less, or 550 Pa-s or less, or 500 Pa-s or less, or 450 Pa-s or less, or 400 Pa-s or less, or 350 Pa-s or less, or 300 Pa-s or less, or 250 Pa-s or less, or 200 Pa-s or less, or 150 Pa-s or less, or 100 Pa-s or less, or 50 Pa-s or less. In some cases, the dielectric polymer has a low viscosity, such as a viscosity of 350 Pa-s or less, such as 300 Pa-s or less, including 250 Pa-s or less. In some instances, a dielectric polymer with a low viscosity may facilitate a higher loading of the thermally conductive filler in the dielectric polymer layer. In certain cases, the viscosities described above are viscosities of the dielectric polymer under high shear conditions, such as a shear rate of 1000/s (e.g., as opposed to low shear conditions, such a shear rate of 100/s).

The dielectric polymer layer may include a dielectric polymer, such as a thermoplastic polymer, a thermosetting polymer, and the like. For example, the dielectric polymer layer may include a polyimide thermoplastic, a polyphenylsulfone, a polyethersulfone, a polytetrafluoroethylene (Teflon), an epoxy-based resin (such as an epoxy resin-based laminate (e.g., woven glass reinforced epoxy resin, such as FR-4, FR-1, etc.) or an epoxy resin-based laminate with woven glass reinforcement over a paper core (e.g., CEM-1 or CEM-3)), and the like. In some cases, the dielectric polymer layer includes a thermoplastic polymer or a thermosetting polymer, as described above, and does not include a liquid crystalline polymer (LCPs) thermoplastic. For instance, the dielectric polymer layer may include substantially no liquid crystalline polymer (LCPs) thermoplastic. In certain embodiments, the dielectric polymer layer includes a polyimide thermoplastic material. In some cases, the dielectric polymer layer is partially crosslinked. Examples of polyimide thermoplastic polymers suitable for embodiments of the present disclosure include, but are not limited to, Extem resin (Sabic Innovative Plastics, Pittsfield, Mass.), a high-temperature amorphous polyimide thermoplastic, for instance, Extem UH resin (e.g., Extem UH1006, UH1006M, UH1016), Extem VH resin (e.g., Extem VH1003, VH1003F, VH1003M, VH1003P), Extem XH resin (e.g., Extem XH1005, XH1015, XH2315, XH1015-1000), combinations thereof, and the like. In certain embodiments, the polyimide thermoplastic material includes Extem XH1005. In certain embodiments, the polyimide thermoplastic material includes Extem XH1015. In certain embodiments, the polyimide thermoplastic material includes Extem XH1015-1000.

In certain embodiments, the dielectric polymer layer conforms to one or more industry specifications for PCBs. For example, the dielectric polymer layer may conform to IPC-4104B/21 specifications, or the relevant industry specifications for the particular PCB being manufactured. Such specifications generally define mechanical and electrical properties for the laminate, which includes the PCB substrate with the adhered electrically conductive layer. These specifications may include the copper peel strength (e.g., when the electrically conductive layer includes copper), minimum flexural strength, maximum water absorption, minimum volume resistivity, minimum surface resistivity, minimum dielectric breakdown, maximum dissipation factor, maximum permittivity, maximum loss tangent, minimum arc resistance, thermal stress, minimum electric strength, flammability, glass transition temperature, and the like.

Thermally Conductive Filler

Embodiments of the printed circuit board (PCB) substrate include a dielectric polymer layer (as described above) that includes a thermally conductive filler. The thermally conductive filler may be configured to increase the thermal conductivity of the dielectric polymer layer to a value greater than the thermal conductivity of the dielectric polymer layer in the absence of the thermally conductive filler. In certain embodiments, the dielectric polymer layer includes an amount of the thermally conductive filler such that the dielectric polymer layer is within its thermal percolation regime. The “thermal percolation regime” is characterized physically by substantially contiguous paths (e.g., substantially uninterrupted by the dielectric polymer material) of the thermally conductive filler from a surface of the PCB substrate to any other surface of the PCB substrate. For example, the dielectric polymer layer may include an amount of thermally conductive filler such that one or more substantially contiguous paths of the thermally conductive filler are present in the dielectric polymer layer that extend from a portion of at least one surface of the dielectric polymer layer to a portion of another surface of the dielectric polymer layer. In some cases, the dielectric polymer layer may include an amount of thermally conductive filler such that one or more substantially contiguous paths of the thermally conductive filler are present in the dielectric polymer layer that extend from at least a portion of the surface of the dielectric polymer to which an electrically conductive layer is attached to a portion of another surface of the dielectric polymer layer, for instance a surface of the dielectric polymer layer opposing the surface to which an electrically conductive layer is attached (e.g., a substantially contiguous path of the thermally conductive filler in the z-axis direction).

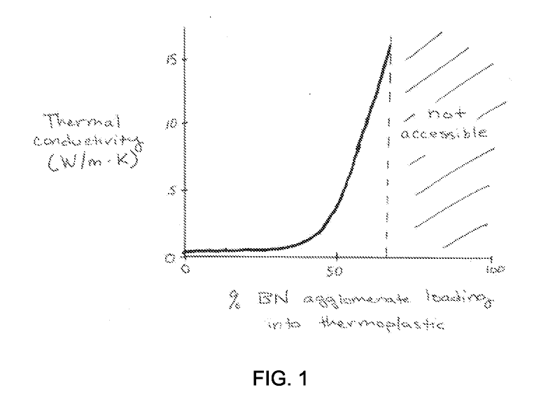

In some instances, the dielectric polymer layer may include the thermally conductive filler in an amount greater than or equal to the dielectric polymer layer's thermal percolation threshold. The “thermal percolation threshold” is characterized quantitatively as an amount (e.g., % mass) of the thermally conductive filler above which there is a significant increase in slope in a plot of thermal conductivity vs. thermally conductive filler loading percentage along an axis of the PCB substrate (see FIG. 1). As shown in FIG. 1, the thermal conductivity of the PCB substrate increases substantially when the % mass of the thermally conductive filler (e.g., boron nitride (BN) agglomerate) is about 45% or more. In certain embodiments, the dielectric polymer layer includes the thermally conductive filler in an amount of 25% or more by mass, such as 30% or more, including 35% or more, or 40% or more, or 45% or more, or 50% or more, or 55% or more, or 60% or more, or 65% or more, or 70% or more, or 75% or more by mass. In some cases, the dielectric polymer layer includes the thermally conductive filler in an amount of 45% or more by mass. In some instances, the dielectric polymer layer includes the thermally conductive filler in an amount of 50% or more by mass.

As described above, the thermally conductive filler may be configured to increase the thermal conductivity of the dielectric polymer layer to a value greater than the thermal conductivity of the dielectric polymer layer in the absence of the thermally conductive filler. In certain embodiments, the thermally conductive filler has a thermal conductivity of 1 W/m·K or more, such as 2 W/m·K, or more, including 3 W/m·K or more, or 4 W/m·K or more, or 5 W/m·K or more, or 6 W/m·K or more, or 7 W/m·K or more, or 8 W/m·K or more, or 9 W/m·K or more, or 10 W/m·K or more. For example, the dielectric polymer layer may include an amount of the thermally conductive filler such that the dielectric polymer layer has a thermal conductivity of 1 W/m·K or more, such as 2 W/m·K, or more, including 3 W/m·K or more, or 4 W/m·K or more, or 5 W/m·K or more, or 6 W/m·K or more, or 7 W/m·K or more, or 8 W/m·K or more, or 9 W/m·K or more, or 10 W/m·K or more in the x-axis direction and/or in the y-axis direction. In certain instances, the dielectric polymer layer may include an amount of the thermally conductive filler such that the dielectric polymer layer has a thermal conductivity of 3 W/m·K or more in the x- and y-axis directions. In some cases, the dielectric polymer layer may include an amount of the thermally conductive filler such that the dielectric polymer layer has a thermal conductivity of 1 W/m·K or more, such as 2 W/m·K, or more, including 3 W/m·K or more, or 4 W/m·K or more, or 5 W/m·K or more, or 6 W/m·K or more, or 7 W/m·K or more, or 8 W/m·K or more, or 9 W/m·K or more, or 10 W/m·K or more in the z-axis direction. For instance, the dielectric polymer layer may include an amount of the thermally conductive filler such that the dielectric polymer layer has a thermal conductivity of 1 W/m·K or more in the z-axis direction. In certain embodiments, the dielectric polymer layer includes an amount of the thermally conductive filler such that the dielectric polymer layer has a thermal conductivity in the x- and/or y-axis directions that is greater than the thermal conductivity in the z-axis direction. As used herein, the x- and y-axes are axes perpendicular to each other in the plane of the PCB substrate, and the z-axis is normal to the plane of the PCB substrate.

In certain embodiments, the thermally conductive filler is a thermally conductive agglomerate filler. By “agglomerate” is meant a group of thermally conductive particles associated with each other into a cluster. In certain instances, the thermally conductive agglomerate filler is configured to have substantially the same thermal conductivity in two or more directions. For example, the thermally conductive agglomerate filler may be configured to have substantially the same thermal conductivity in all three dimensions. The thermally conductive agglomerate filler may be composed of thermally conductive particles that are associated together into an agglomerate particle. The agglomerate particle may provide a thermally conductive filler, such that the thermal conductivities of the individual particles in the agglomerate are averaged out and the thermally conductive agglomerate filler has substantially the same thermal conductivity in all three dimensions. For instance, anisotropic thermally conductive filler particles may be associated together into thermally conductive agglomerate particles. The thermally conductive agglomerate particles may be configured such that the individual anisotropic filler particles are randomly oriented in the agglomerate. As such, the thermally conductive agglomerate filler has a thermal conductivity that is substantially isotropic.

In certain embodiments, the thermally conductive filler is distributed substantially homogeneously in the dielectric polymer layer. For example, the thermally conductive filler may be distributed such that the concentration of thermally conductive filler in the dielectric polymer layer is not localized to any particular area within the dielectric polymer layer. In other embodiments, the thermally conductive filler is distributed heterogeneously in the dielectric polymer layer. For instance, the thermally conductive filler may be distributed unevenly in the dielectric polymer layer such that the concentration of thermally conductive filler is greater in some areas of the dielectric polymer layer than other areas of the dielectric polymer layer. In some cases, the thermally conductive filler may be distributed in the dielectric polymer layer such that the thermally conductive polymer is localized near a surface of the PBC substrate, such as near the surface of the PCB substrate to which the electrically conductive layer and/or the heat-producing components are attached.

In certain embodiments, the thermally conductive filler includes a metal nitride, a metal oxide, a carbon material, or combinations thereof. The thermally conductive filler may be a metal nitride, such as, but not limited to boron nitride, aluminum nitride, combinations thereof, and the like. In some cases, the thermally conductive filler is a metal oxide, such as, but not limited to, aluminum oxide, and the like. In certain instances, the thermally conductive filler is a carbon material, such as, but not limited to, carbon, carbon black, graphite, carbon nanotubes, combinations thereof, and the like. For instance, in certain embodiments, the thermally conductive filler is boron nitride. As described above, the thermally conductive filler may be a thermally conductive agglomerate filler, and as such, the thermally conductive agglomerate filler may include agglomerate boron nitride. In certain cases, the agglomerate boron nitride includes hexagonal boron nitride. Typically, hexagonal boron nitride may have a plate-like form, which may tend to orient its configuration such that the plate-like particle planes are parallel to the surface of the PCB substrate. This non-random orientation may introduce anisotropy into the thermal conductivity properties of the PCB substrate, such that, in the case of plate-like particles, the thermal conductivity in the plane of the PCB substrate is greater than the thermal conductivity perpendicular to the plane. However, as described above regarding agglomerate particles, agglomerate boron nitride may be configured such that the thermally conductive agglomerate boron nitride filler has a thermal conductivity that is substantially isotropic (e.g., substantially the same in all directions).

In certain embodiments, the thermally conductive filler (e.g., the thermally conductive agglomerate filler) includes micro-sized particles. For instance, the thermally conductive filler may have an average particle size ranging from 1 μm to 1000 μm, such as from 10 μm to 750 μm, including from 25 μm to 500 μm, or from 50 μm to 250 μm, for example from 50 μm to 150 μm. In some embodiments, the thermally conductive filler has an average particle size ranging from 50 μm to 250 μm. In some cases, the thermally conductive filler has an average particle size of 50 μm. In certain instances, the thermally conductive filler has an average particle size of 75 μm. In certain embodiments, the thermally conductive filler has an average particle size of 125 μm. In some embodiments, the thermally conductive filler has an average particle size of 125 μm to 150 μm. In other instances, the thermally conductive filler has an average particle size of 250 μm. In certain embodiments, the thermally conductive filler has a particle size of 1000 μm or less, such 750 μm or less, including 500 μm or less, or 250 μm or less, for example 150 μm or less, or 125 μm or less, or 100 μm or less, or 75 μm or less, or 50 μm or less, or 25 μm or less. In some embodiments, the thermally conductive filler has a particle size of 125 μm or less. In some cases, the thermally conductive filler has a particle size of 75 μm or less. In certain instances, the thermally conductive filler has a particle size of 50 μm or less.

Embodiments of the thermally conductive filler may have other physical properties as described below. In certain embodiments, the thermally conductive filler has a dielectric strength (e.g., the maximum electric field strength that it can withstand intrinsically without breaking down or without experiencing a significant decrease in its insulating properties) of 5 kV/mm or more, such as 10 kV/mm or more, including 15 kV/mm or more, or 20 kV/mm or more, or 25 kV/mm or more, or 30 kV/mm or more, or kV/mm or more, or 40 kV/mm or more, or 45 kV/mm or more, or 50 kV/mm or more, or 55 kV/mm or more, or 60 kV/mm or more, or 65 kV/mm or more, or 70 kV/mm or more, or 75 kV/mm or more, or 80 kV/mm or more, or 85 kV/mm or more, or 90 kV/mm or more, or 95 kV/mm or more, or 100 kV/mm or more. In certain instances, the thermally conductive filler has a dielectric field strength of 30 kV/mm or more.

In certain embodiments, the thermally conductive filler has an volume resistivity (e.g., electrical resistivity; a measure of how strongly a material opposes the flow of electric current) of 1×10⁵ ohm·cm or more, or 1×10⁶ ohm·cm or more, or 1×10⁷ ohm·cm or more, or 1×10⁸ ohm·cm or more, or 1×10⁹ ohm·cm or more, or 1×10¹⁰ ohm·cm or more, or 1×10¹¹ ohm·cm or more, or 1×10¹² ohm·cm or more, or 1×10¹³ ohm·cm or more, or 1×10¹⁴ ohm·cm or more, or 1×10¹⁵ ohm·cm or more. In some cases, the thermally conductive filler has a volume resistivity of 1×10⁸ ohm·cm or more.

In certain embodiments, the thermally conductive filler has a Moh's hardness of 5 or less, such as 4 or less, or 3 or less, or 2 or less, or 1 or less. In some cases, the thermally conductive filler has a Moh's hardness of 4 or less. A thermally conductive filler with a Moh's hardness of 4 or less may facilitate the fabrication of PCBs by minimizing damage to the PCB fabrication tools.

In certain embodiments, the thermally conductive filler has a high tap density. By “tap density” or “tapped density” is meant the bulk density of powders, granules or other divided solids (e.g., the thermally conductive filler) measured as the mass of many particles of the material divided by the total volume they occupy. For example, the tap density may be measured by placing a specified amount of powder in a container and tapping (e.g., vibrating) the container until no further decrease in the volume of the powder takes place. The mass of the powder divided by its volume after tapping gives its tap density. In certain cases, the thermally conductive filler has a tap density of 0.5 g/cm³ or more, or 0.55 g/cm³ or more, such as 0.6 g/cm³ or more, or 0.65 g/cm³ or more, including 0.7 g/cm³ or more, or 0.75 g/cm³ or more, or 0.8 g/cm³ or more, or 0.85 g/cm³ or more, or 0.9 g/cm³ or more, or 0.95 g/cm³ or more, or 1 g/cm³ or more. For instance, the thermally conductive filler may have a tap density of 0.7 g/cm³ or more, or 0.75 g/cm³ or more, or 0.8 g/cm³ or more.

Suitable thermally conductive fillers include, but are not limited to, agglomerated hexagonal boron nitride particles, such as PCTH2 MHF (51 μm maximum particle size; Saint-Gobain Corp., Valley Forge, Pa.), PCTH3 MHF (76 μm maximum particle size; Saint-Gobain Corp., Valley Forge, Pa.); PCTH5 MHF (127 μm maximum particle size; Saint-Gobain Corp., Valley Forge, Pa.), PT-350 (125-150 μm particle size; Momentive, Columbus, Ohio), PT-360 (250 μm particle size; Momentive, Columbus, Ohio), and PT-370 (250 μm particle size; Momentive, Columbus, Ohio).

Electrically Conductive Layer

In certain embodiments, the printed circuit board (PCB) includes an electrically conductive layer disposed on the dielectric polymer layer. The electrically conductive layer may be configured to be electrically conductive. In some cases, the electrically conductive layer includes a substantially contiguous layer disposed on at least a portion of a surface of the dielectric polymer layer. In certain instances, the electrically conductive layer may include a pattern of electrically conductive material disposed on at least a portion of the dielectric polymer layer. For example, the electrically conductive layer may include a set of traces. In these embodiments, the electrically conductive layer may be configured to electrically connect electronic components mounted on the PCB via conductive pathways (e.g., the traces) provided in the electrically conductive layer.

The electrically conductive layer may include a conductive material, such as a metal. The electrically conductive layer may include a metal, such as copper, gold, silver, tin, nickel, combinations thereof, and the like. In certain instances, the electrically conductive layer includes copper.

In certain cases, the electrically conductive layer is bonded to the dielectric polymer layer. The electrically conductive layer may be bonded directly to the dielectric polymer layer such that the electrically conductive layer directly contacts and is bonded to the dielectric polymer layer. For example, the electrically conductive layer may form a physical and/or chemical bond to the dielectric polymer layer. In other embodiments, the electrically conductive layer is indirectly bonded to the dielectric polymer layer. For instance, the printed circuit board may include a bonding layer between the dielectric polymer layer and the electrically conductive layer that is configured to bond the electrically conductive layer to the dielectric polymer layer. The bonding layer may include, but is not limited to, a silicone adhesive, an epoxy adhesive, and the like.

In certain embodiments, the electrically conductive layer is bonded to the dielectric polymer layer such that the electrically conductive layer does not significantly delaminate from the dielectric polymer layer during use. The electrically conductive layer may be bonded to the dielectric polymer layer such that the printed circuit board has relatively high peel strength between the electrically conductive layer and the dielectric polymer layer. For instance, the PCB may have a peel strength between the electrically conductive layer and the dielectric polymer layer of 2 pounds per inch width or more, such as 3 pounds per inch width or more, including 4 pounds per inch width or more, or 5 pounds per inch width or more, or 6 pounds per inch width or more, or 7 pounds per inch width or more, or 8 pounds per inch width or more, or 9 pounds per inch width or more, or 10 pounds per inch width or more.

In some embodiments, the PCB includes one or more electrically conductive layers bonded to the dielectric polymer layer. The PCB may include a first electrically conductive layer bonded to a first surface of the dielectric polymer layer. In some cases, the PCB may include a second electrically conductive layer bonded to a second surface of the dielectric polymer layer. For example, the PCB may include a dielectric polymer layer with a first electrically conductive layer bonded to a first surface of the dielectric polymer layer and a second electrically conductive layer bonded to a second surface of the dielectric polymer layer. In some instances, the first and second surfaces of the dielectric polymer layer are opposing sides of the dielectric polymer layer.

### Methods

Aspects of the present disclosure include methods of producing the subject printed circuit boards. In certain embodiments, the method includes mixing a dielectric polymer with a thermally conductive filler, and forming a dielectric polymer layer that includes the dielectric polymer and the thermally conductive filler. In some cases, the forming of the dielectric polymer layer includes extruding the dielectric polymer layer that includes the dielectric polymer and the thermally conductive filler. Other methods of forming the dielectric polymer layer are also possible, such as, but not limited to, molding the dielectric polymer layer, such as injection molding the dielectric polymer layer.

In some embodiments, the method further includes bonding an electrically conductive layer to the dielectric polymer layer. The bonding may be achieved according to various methods, such as, but not limited to the following: molding (e.g., injection molding); lamination, where the dielectric polymer layer is laminated to the electrically conductive layer; thin film deposition, where the electrically conductive layer is deposited on a surface of the dielectric polymer layer by physical vapor deposition (PVD) or chemical vapor deposition (CVD) processes; bonding, where a bonding layer (e.g., adhesive layer) is provided between the dielectric polymer layer and the electrically conductive layer; combinations thereof, and the like.

Embodiments of the method may further include forming a set of traces in the electrically conductive layer. The method may include forming the set of traces in the electrically conductive layer after the electrically conductive layer has been bonded to the dielectric polymer layer. For example, the method may include photolithography methods, etching the electrically conductive layer, milling the electrically conductive layer, combinations thereof, and the like. In other embodiments, the method may include bonding the electrically conductive layer to the dielectric polymer layer in the form of a set of traces. In these embodiments, the method includes masking the dielectric polymer layer in a pattern of masked and unmasked portions and depositing the electrically conductive layer on at least the unmasked portions of the dielectric polymer layer. Bonding the electrically conductive layer to the dielectric polymer layer in the form of a set of traces may facilitate a minimization in the number of steps in the PCB fabrication process by directly forming the set of traces on the dielectric polymer layer such that a subsequent photolithography or etching step is not required.

In certain embodiments, the method further includes forming one or more vias in the PCB. The vias may be positioned at the end of an electrically conductive trace. In some cases, the via may be formed in the PCB by drilling one or more holes through the PCB. In some cases, the drilling may include drilling holes in the PCB using a drill or a laser. The resulting holes in the PCB may then be filled with an electrically conductive material to form an electrically conductive via through the PCB. One or more electrical components may be mounted on the PCB, for example by soldering the electrical components to the surface of the PCB (e.g., for surface-mount components) or by soldering electrically conductive elements of the electrical component that extend through the vias in the PCB (e.g., for through-hole mounted components).

In some instances, the method includes mixing the dielectric polymer with a thermally conductive agglomerate filler such that the thermally conductive agglomerate filler is not substantially degraded by the mixing process. For instance, the thermally conductive agglomerate filler may be mixed with the dielectric polymer such that the thermally conductive agglomerate particles are exposed to a minimum of shearing forces. In some cases, minimizing the shearing forces on the thermally conductive agglomerate filler may facilitate maintaining the thermally conductive filler in its agglomerate form without significant degradation of the agglomerate particles into anisotropic particles. In certain instances, minimizing the degradation of the agglomerate particles includes one or more of including a lower viscosity thermoplastic, side feeding the agglomerate particles such that the agglomerate particles are subjected to a minimal processing time, and the like.

### Utility

Printed circuit boards as disclosed herein find use in a variety of different applications. For example, the subject thermally conductive printed circuit boards find use in electronics applications where the dissipation of heat from electronic components is desired. The subject thermally conductive PCBs find use in dissipating heat from heat-producing components mounted on the PCB such as a relay (e.g., a solid state relay), a resistor (e.g., a variable resistor, a thermistor, a humistor, a varistor, etc.), a fuse, a circuit breaker, a capacitor, a transformer, a motor, a transducer, a diode (e.g., a light-emitting diode (LED), etc.), a transistor, an integrated circuit, and the like. In certain embodiments, the subject PCBs find use in applications where the use of a separate heat sink is not desired, for example where size and/or space requirements for the PCB require a minimization in the number and/or size of the components mounted on the PCB. In some instances, the subject thermally conductive PCBs may facilitate a minimization in the production costs associated with the PCBs by eliminating the need for additional heat sink components.

### Kits

Also provided are kits that find use in practicing the subject methods, as described above. For example, kits for practicing the subject methods may include a printed circuit board (PCB) substrate as described herein. The PCB substrate may be provided as the dielectric polymer layer itself, as a PCB substrate with an electrically conductive layer bonded to a surface of the dielectric polymer layer, or as a PCB substrate with a set of electrically conductive traces bonded to a surface of the dielectric polymer layer. In certain embodiments, the kits include a sealed package configured to maintain the sterility of the PCB and/or PCB substrate. The sealed package may be sealed such that substantially no external contaminants, such as dirt, microbes, liquids, gases, and the like, are able to enter the sealed package. For example, the sealed package may be sealed such that the package is water-tight and/or air-tight. In some embodiments, the sealed package may be an antistatic package configured to minimize electrostatic damage to the PCB and/or components mounted on the PCB.

In addition to the above components, the subject kits may further include instructions for practicing the subject methods. These instructions may be present in the subject kits in a variety of forms, one or more of which may be present in the kit. One form in which these instructions may be present is as printed information on a suitable medium or substrate, e.g., a piece or pieces of paper on which the information is printed, in the packaging of the kit, in a package insert, etc. Another means would be a computer readable medium, e.g., CD, DVD, Blu-ray, computer-readable memory, etc., on which the information has been recorded or stored. Yet another means that may be present is a website address which may be used via the Internet to access the information at a removed site. Any convenient means may be present in the kits.

As can be appreciated from the disclosure provided above, the present disclosure has a wide variety of applications. Accordingly, the following examples are offered for illustration purposes and are not intended to be construed as a limitation on the invention in any way. Those of skill in the art will readily recognize a variety of noncritical parameters that could be changed or modified to yield essentially similar results. Thus, the following examples are put forth so as to provide those of ordinary skill in the art with a complete disclosure and description of how to make and use the present invention, and are not intended to limit the scope of what the inventors regard as their invention nor are they intended to represent that the experiments below are all or the only experiments performed. Efforts have been made to ensure accuracy with respect to numbers used (e.g. amounts, temperature, etc.) but some experimental errors and deviations should be accounted for. Unless indicated otherwise, parts are parts by weight, molecular weight is weight average molecular weight, temperature is in degrees Celsius, and pressure is at or near atmospheric.

### EXAMPLES

### Example 1

An example describing an embodiment of the present disclosure is described in detail below. All materials were dried for at least 3 h at 300° F. (about 150° C.) before compounding. Extem XH1015-1000 resin (Sabic Innovative Plastics, Pittsfield, Mass.) at 51.3% by mass was compounded with boron nitride (BN) agglomerate PCTH3 MHF (3 mil (about 75 μm) diameter, Saint-Gobain Corp., Valley Forge, Pa.) at 48.7% by mass using a 26 mm Coperion Twin Screw Extruder with a 05A-D001(A) screw design, a screw speed of 500 RPMs, a multi-zone temperature profile of 350-350-370-380-380-380-390-390° C., a feed rate of 20.52 pounds per hour (about 9.31 kg/hr) of Extem XH1015-1000 (upstream), a feed rate of 19.48 pounds per hour (about 8.84 kg/hr) of PCTH3 MHF (downstream feed with 100 RPM side screw), a total feed rate of 40 pounds per hour (about 18.14 kg/hr), and a Z1 die for pelleting (Polymics, Ltd., State College, Pa.). A total of 15.66 lb (about 7.1 kg) of material was compounded, and the target composition was verified by ashing at 600° C. for 1 h.

### Example 2

A second example describing an embodiment of the present disclosure is described in detail below. All materials were dried for at least 3 h at 300° F. (about 150° C.) before compounding. Extem XH1015-1000 resin (Sabic Innovative Plastics, Pittsfield, Mass.) at 47% by mass was compounded with boron nitride (BN) agglomerate PCTH5 MHF (5 mil (about 125 μm) diameter, Saint-Gobain Corp., Valley Forge, Pa.) at 53% by mass using a 26 mm Coperion Twin Screw Extruder with a 05A-D001(A) screw design, a screw speed of 350 RPMs, a multi-zone temperature profile of 340-340-360-370-380-380-390-390° C., a feed rate of 18.8 pounds per hour (about 8.53 kg/hr) of Extem XH1015-1000 (upstream), a feed rate of 21.2 pounds per hour (about 9.62 kg/hr) of PCTH5 MHF (downstream feed with 100 RPM side screw), a total feed rate of 40 pounds per hour (about 18.14 kg/hr), and a Z1 die for pelleting (Polymics, Ltd., State College, Pa.). A total of 21.86 lb (about 9.92 kg) of material was compounded, and the target composition was verified by ashing at 600° C. for 1 h.

### Example 3

A sheet of thermally conductive substrate was generated from the Extem XH1015-1000/PCTH3 MHF (51.3:48.7 by mass) compounded material in pellet form using a 1.0 inch, 24:1 single-screw extruder with Barrier Maddock Screw, a 9-inch-wide coat hanger film die, and a downstream setup consisting of a three-roll vertical downstack, a rubber top roll, and chrome middle and bottom rows (SABIC Innovative Plastics, Pittsfield, Mass.). The compounded material was dried for 6 h at 350° F. (about 175° C.) prior to extrusion into sheet. The processing conditions were as follows: multi-zone temperature profile of 680-700-720-740-740-740° F. (about 360-370-380-390-390-390° C.), corresponding to zone 1-zone 2-zone 3-zone 4-adapter-die, screw speed of 50.2 rpm, pressure of 2350 psi (about 16,200 kPa), middle roll temp of 350° F. (about 175° C.), and roll speed of 2.0-2.5 ft/min (about 60-75 cm/min). Fiberglass was used as insulation around the die. The extrudate was not wrapped around the rolls, but rather kissed on the middle roll and pulled straight through. These conditions yielded a sheet ranging in thickness from 0.018 in to 0.028 in (about 0.46 mm to 0.71 mm), with a width of 8.5 in to 9.0 in (about 21.6 cm to 22.9 cm). The resulting substrate exhibited a thermal conductivity of 3.52 W/m·K at 25° C. in the x and y directions (ASTM E-1225, Precision Measurements and Instruments Corporation, Oregon), and a thermal conductivity>1.0 W/m·K in the z direction (Kyosha, Co. Ltd., Japan). To an 8 in by 12 in sheet of thermally conductive substrate was adhered TWS high performance copper foil (1 oz/sq ft, Circuit Foil) by pressing in a hydraulic thermal press at 500 psi (about 3450 kPa) for 30 min at 570° F. (about 300° C.) and then cooling to 400° F. (about 205° C.) before releasing the pressure (Evenstar, Inc., Santa Clara, Calif.). The resulting laminate had a copper peel strength of about 8 pounds per inch width (BAE Systems, Santa Clara, Calif.).

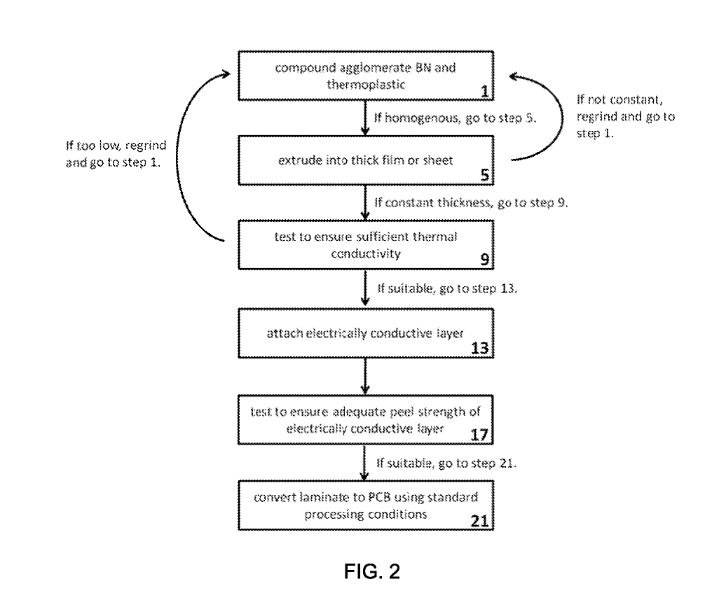

The laminate was processed as follows to generate a circuit (e.g., for a printed circuit board): drilling, electroless copper deposition, mechanical scrubbing of surface, dry film imaging of the circuit pattern, electroplating copper/tin, strip drying film, etching circuit pattern, tin stripping, mechanical scrub of surface, solder mask application, solder mask curing at 300° F. (about 150° C.) for 60 minutes, and routing (Evenstar, Inc., Santa Clara, Calif.). A flow chart for the entire process is shown in FIG. 2.

Although the foregoing invention has been described in some detail by way of illustration and example for purposes of clarity of understanding, it is readily apparent to those of ordinary skill in the art in light of the teachings of this invention that certain changes and modifications may be made thereto without departing from the spirit or scope of the appended claims. It is also to be understood that the terminology used herein is for the purpose of describing particular embodiments only, and is not intended to be limiting, since the scope of the present invention will be limited only by the appended claims.

Accordingly, the preceding merely illustrates the principles of the invention. It will be appreciated that those skilled in the art will be able to devise various arrangements which, although not explicitly described or shown herein, embody the principles of the invention and are included within its spirit and scope. Furthermore, all examples and conditional language recited herein are principally intended to aid the reader in understanding the principles of the invention and the concepts contributed by the inventors to furthering the art, and are to be construed as being without limitation to such specifically recited examples and conditions. Moreover, all statements herein reciting principles, aspects, and embodiments of the invention as well as specific examples thereof, are intended to encompass both structural and functional equivalents thereof. Additionally, it is intended that such equivalents include both currently known equivalents and equivalents developed in the future, i.e., any elements developed that perform the same function, regardless of structure. The scope of the present invention, therefore, is not intended to be limited to the embodiments shown and described herein. Rather, the scope and spirit of present invention is embodied by the appended claims.

That which is claimed is:

1. A printed circuit board comprising:
a dielectric polymer layer comprising a thermally conductive agglomerate filler; and
an electrically conductive layer bonded to the dielectric polymer layer.

2. The printed circuit board of claim 1, wherein the dielectric polymer layer comprises an amount of the thermally conductive agglomerate filler greater than or equal to the dielectric polymer layer's thermal percolation threshold.

3. The printed circuit board of claim 1, wherein the dielectric polymer layer comprises the thermally conductive agglomerate filler in an amount of 45% or more by mass.

4. The printed circuit board of claim 1, wherein the thermally conductive agglomerate filler comprises a material selected from a group consisting of a metal nitride, a metal oxide, a carbon material and combinations thereof.

5. The printed circuit board of claim 4, wherein the thermally conductive agglomerate filler comprises boron nitride.

6. The printed circuit board of claim 5, wherein the thermally conductive agglomerate filler comprises hexagonal boron nitride.

7. The printed circuit board of claim 1, wherein the thermally conductive agglomerate filler has an average particle size ranging from 50 μm to 250 μm.

8. The printed circuit board of claim 1, wherein the dielectric polymer layer comprises a thermoplastic material.

9. The printed circuit board of claim 8, wherein the thermoplastic material comprises a polyimide thermoplastic.

10. The printed circuit board of claim 1, wherein the electrically conductive layer comprises a set of traces.

11. The printed circuit board of claim 1, further comprising a bonding layer between the dielectric polymer layer and the electrically conductive layer configured to bond the electrically conductive layer to the dielectric polymer layer.

12. The printed circuit board of claim 1, wherein the electrically conductive layer is bonded directly to the dielectric polymer layer.

13. The printed circuit board of claim 1, wherein the electrically conductive layer comprises a metal.

14. The printed circuit board of claim 13, wherein the metal comprises copper.

15. The printed circuit board of claim 1, wherein the printed circuit board has a peel strength between the electrically conductive layer and the dielectric polymer layer of 4 pounds per inch width or more.

16. The printed circuit board of claim 1, wherein the dielectric polymer layer has a thermal conductivity of 3 W/m·K or more in the x- and y-axis directions.

17. The printed circuit board of claim 1, wherein the dielectric polymer layer has a thermal conductivity of 1 W/m·K or more in the z-axis direction.

18. The printed circuit board of claim 1, further comprising a second electrically conductive layer bonded to a second side of the dielectric polymer layer.

19. The printed circuit board of claim 1, wherein the dielectric polymer layer does not include a liquid crystal polymer.

20. A method of producing a printed circuit board, the method comprising:
mixing a dielectric polymer with a thermally conductive agglomerate filler; and
extruding a dielectric polymer layer comprising the dielectric polymer and the thermally conductive agglomerate filler.

21. The method of claim 20, further comprising bonding an electrically conductive layer to the dielectric polymer layer.

22. The method of claim 21, further comprising forming a set of traces in the electrically conductive layer.

23. The method of claim 21, wherein the bonding comprises masking the dielectric polymer layer in a pattern of masked and unmasked portions and depositing the electrically conductive layer on at least the unmasked portions of the dielectric polymer layer.

24. A printed circuit board substrate comprising a dielectric polymer layer comprising a thermally conductive agglomerate filler.

25. The printed circuit board substrate of claim 24, further comprising an electrically conductive layer bonded to the dielectric polymer layer.

26. The printed circuit board substrate of claim 24, wherein the dielectric polymer layer comprises an amount of the thermally conductive agglomerate filler greater than or equal to the dielectric polymer layer's thermal percolation threshold.
